(19) United States
(12) Patent Application Publication
(10) Pub. No.: US 2026/0268042 A1
(43) Pub. Date: Sep. 10, 2026

(54) GRAPH NEURAL NETWORKS THAT MODEL FACE-FACE INTERACTIONS BETWEEN MESHES

(71) Applicant: DeepMind Technologies Limited, London (GB)

(72) Inventors: Kelsey Rebecca Allen, London (GB); Yulia Rubanova, London (GB); Tatiana Lopez Guevara, Edinburgh (GB); William Fairclough Whitney, London (GB); Alvaro Sanchez, London (GB); Peter William Battaglia, London (GB); Tobias Pfaff, London (GB)

(21) Appl. No.: 18/873,202

(22) PCT Filed: Sep. 27, 2023
(86) PCT No.: PCT/EP2023/076797

§ 371 Date: Dec. 9, 2024

Related U.S. Application Data
(60) Provisional application No. 63/411,018, filed on Sep. 28, 2022.
(60) Provisional application No. 63/411,418, filed on Sep. 29, 2022.

(51) Int. Cl. G06F 30/27; B25J 9/16; G06N 3/084

(52) U.S. Cl. CPC G06F 30/27; B25J 9/1671; G06N 3/084

(57) ABSTRACT

Methods, systems, and apparatus, including computer programs encoded on a computer storage medium, for simulating a state of an environment over a sequence of time steps. In one aspect, a method comprises, at each of one or more time steps: obtaining an environment mesh representing the state of the environment at the time step; generating a graph representing the state of the environment at the time step, comprising: determining that a first face of a first object mesh is within a collision distance of a second face of a second object mesh; and in response, instantiating a face-face edge in the graph that connects: (i) a first set of graph nodes in the graph that represent the first face in the first object mesh, and (ii) a second set of graph nodes in the graph that represent the second face in the second object mesh.

### CROSS-REFERENCE TO RELATED APPLICATION

This application claims priority to U.S. Provisional Applications No. 63/411,018, filed on Sep. 28, 2022, and No. 63/411,418, filed on Sep. 29, 2022. The disclosure of the prior applications is considered part of and is incorporated by reference in the disclosure of this application.

### BACKGROUND

This specification relates to processing data using machine learning models.

Machine learning models receive an input and generate an output, e.g., a predicted output, based on the received input. Some machine learning models are parametric models and generate the output based on the received input and on values of the parameters of the model.

Some machine learning models are deep models that employ multiple layers of models to generate an output for a received input. For example, a deep neural network is a deep machine learning model that includes an output layer and one or more hidden layers that each apply a non-linear transformation to a received input to generate an output.

### SUMMARY

This specification generally describes a simulation system implemented as computer programs on one or more computers in one or more locations that simulates the state of an environment over a sequence of time steps.

Throughout this specification, a “mesh” refers to data defining a collection of interconnected (mesh) nodes, (mesh) edges, and (mesh) faces that define the shape and structure of an object, e.g., a three-dimensional object. Each edge in the mesh connects a respective pair of nodes in the mesh, and each face in the mesh is specified by a respective set of multiple nodes, e.g., three nodes to define a triangular face, or four nodes to define a quadrilateral face.

Throughout this specification, an “object” can refer to any physical or tangible entity, including, e.g., surfaces, machinery, equipment, tools, products, or components thereof.

Throughout this specification, an “embedding” can refer to an ordered collection of numerical values, e.g., a vector, matrix, or other tensor of numerical values.

Throughout this specification, a “block” in a neural network can refer to a collection of one or more neural network layers in the neural network.

Throughout this specification, a first neural network can be referred to as a “subnetwork” of a second neural network if the first neural network is included in the second neural network.

Particular embodiments of the subject matter described in this specification can be implemented so as to realize one or more of the following advantages.

The system described in this specification enables accurate and computationally efficient simulation of environments, e.g., physical environments which include objects that can come into contact (collide) with one another. Resolving collisions during simulations can be computationally expensive. As the number of objects in the environment and the complexity of the shape of each object increases, exponentially more interactions must be considered to accurately simulate the effects of collisions. For instance, a simulator can resolve the effects of a collision between objects by considering distances between nodes included in mesh representations of the objects. However, for objects with complex mesh representations, evaluating and processing distances between large numbers of individual nodes can become prohibitively expensive. The system described in this specification addresses these issues by, rather than characterizing collisions in terms of distances between particles making up objects, instead parameterizing collisions as interactions between faces of object meshes. By computing interactions of mesh surface elements (faces) instead of nodes, the system can accurately and efficiently model collisions using sparse mesh representations, thus improving computational efficiency and also enabling the system to outperform analytic simulators in real-world simulation tasks.

The system described in this specification may be particularly effective for simulating rigid-body physics, e.g., environments with one multiple colliding rigid bodies. Simulating rigid body collisions among arbitrary shapes is notoriously difficult due to the complex geometry and strong non-linearity of the interactions. Existing methods that model collisions through mesh nodes are often inaccurate because they struggle when collisions occur on faces far from nodes. Alternative approaches that represent objects densely with many particles can be prohibitively expensive for complex objects. To address these issues, as described throughout this specification, the system can compute interactions between mesh faces in addition to mesh nodes. More specifically, the system can extend message passing from graphs with edges between nodes to graphs with hyper-edges between mesh faces, thus allowing accurate and efficient collision handling on sparse meshes without missing collisions. Compared to certain node- and particle-based methods, the system can achieve higher accuracy (e.g., by a factor of four times) in simulating complex shape interactions, while also being more computationally efficient (e.g., by a factor of eight times) on sparse, rigid meshes. Moreover, the system can learn frictional dynamics directly from real-world data, and can be more accurate than analytical solvers given modest amounts of training data.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows an example simulation system.

FIG. 2 is a flow diagram of an example process for simulating the state of an environment over a sequence of time steps.

FIG. 3 is a flow diagram of an example process for processing a current environment mesh to generate a graph representing the current state of the environment at a time step.

FIG. 4 is a flow diagram of an example process for processing a graph representing the current state of the environment using a graph neural network to generate an updated graph.

FIG. 5 is a flow diagram of an example process for training a graph neural network.

FIG. 6 provides an illustration of face-face edges, mesh edges, object nodes, mesh modes, and object-level nodes.

FIG. 7 provides an illustration of the features that can be computed for a face-face edge that connects a first mesh face and a second mesh face.

FIG. 8 illustrates how various simulation models treat colliding objects.

FIG. 9 shows experimental results comparing the performance of the simulation system described in this specification with other simulation systems.

Like reference numbers and designations in the various drawings indicate like elements.

### DETAILED DESCRIPTION

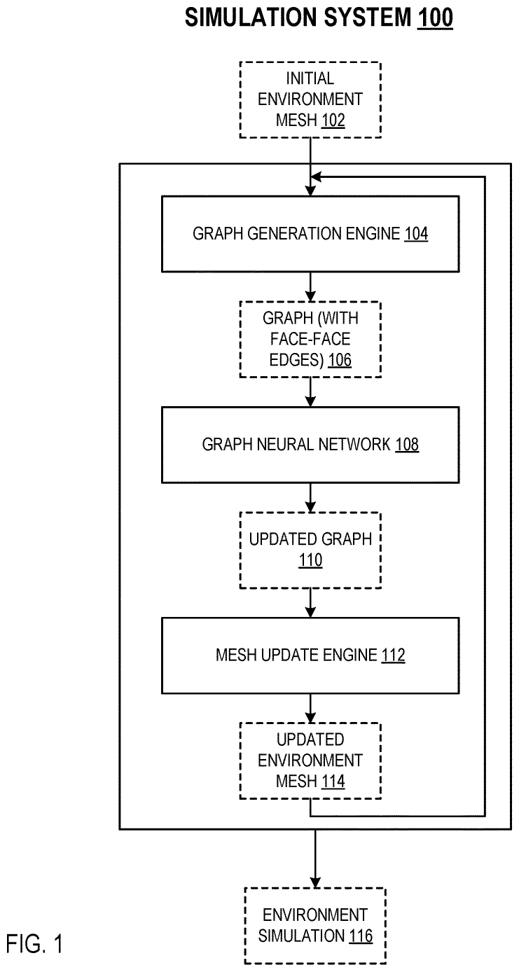

FIG. 1 shows an example simulation system 100. The simulation system 100 is an example of a system implemented as computer programs on one or more computers in one or more locations in which the systems, components, and techniques described below are implemented.

The system 100 is configured to receive an initial environment mesh 102 that defines an initial state of an environment. In particular, the initial environment mesh 102 defines the initial shapes, orientations, and positions of one or more objects in the environment. The initial environment mesh 102 can include multiple “object meshes” that each represent a respective object in the environment and that collectively define the overall initial environment mesh 102.

The system 100 processes the initial environment mesh 102 to generate a simulation 116 of the environment. The simulation 116 defines a sequence of environment meshes, including a respective environment mesh for each time step in a sequence of time steps. The simulation 116 thus describes the evolution of the environment over the sequence of time steps, in particular, describing how the shapes, orientations, and positions of the objects represented in the initial environment mesh 102 change over time, e.g., as a result of collisions or other interactions between the objects in the environment. The sequence of time steps can include any appropriate number of time steps, e.g., 10 time steps, 1000 time steps, or 100,000 time steps.

The environment can be any appropriate environment, e.g., a real-world physical environment, e.g., a manufacturing environment, a warehouse environment, a roadway environment, and so forth. The environment can include one or more agents that interact with the environment, e.g., robotic agents, vehicles, and so forth. The environment can include any of a variety of objects, e.g., tools, packages, mechanical parts, electrical parts, walls, floors, roadway surfaces, conveyor belt surfaces, and so forth.

The system 100 includes a graph generation engine 104, a graph neural network 108, and a mesh update engine 112, which are each described in more detail next.

The graph generation engine 104 is configured to process a current environment mesh that represents the state of the environment at a time step to generate data defining a corresponding graph 106. The current environment mesh can be, e.g., the initial environment mesh representing the state of the environment at the first time step, or a subsequent environment mesh representing the state of the environment at a subsequent time step (i.e., after the first time step).

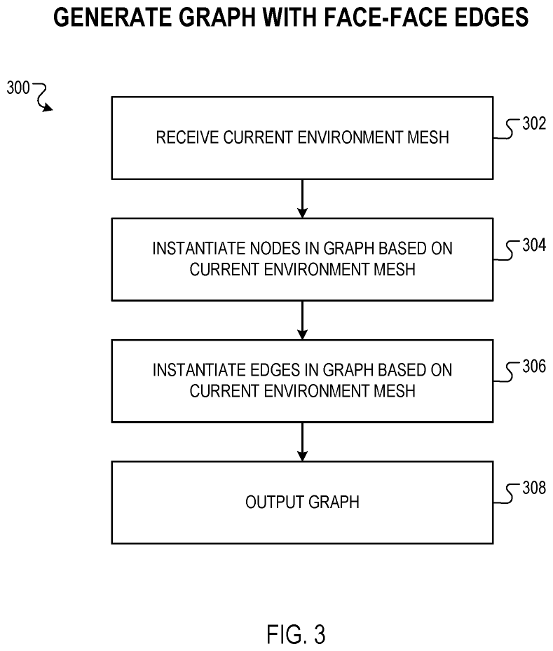

The graph 106 includes: (i) a collection of graph nodes, and (ii) a collection of graph edges. Each graph node can be associated with a respective set of node features, and each graph edge can be associated with a respective set of edge features. Example techniques for generating graph node features and graph edge features are described in more detail below with reference to FIG. 3.

The collection of graph nodes can include a respective graph node corresponding to each mesh node in the current environment mesh and, optionally, a respective graph node corresponding to each of one or more objects in the environment. A graph node corresponding to an object (as opposed to, e.g., a graph node corresponding to a mesh node) may be referred to for convenience as an “object node” in this specification. The object nodes can be understood as virtual nodes that, rather than representing a specific mesh node, represent the existence of an object in the environment. The object nodes can facilitate efficient information propagation between the graph nodes during processing of the graph 106 by the graph neural network 108, as will be described in more detail below.

The collection of graph edges can include edges designated as “node-node edges,” “face-face edges,” and “object-node edges.”

Each node-node edge in the graph 106 defines a connection between a first graph node representing a first mesh node and a second graph node representing a second mesh node. The graph generation engine 104 can instantiate a respective node-node edge in the graph representing each mesh edge in the current environment mesh. That is, for each mesh edge between a pair of mesh nodes in the current environment mesh, the graph generation engine 104 can generate a corresponding node-node edge in the graph between the pair of graph nodes representing the pair of mesh nodes. Thus the node-node edges in the graph 106 can be understood as representing the mesh edges connecting the mesh nodes in the current environment mesh.

Each face-face edge defines a connection between: (i) a first set of (multiple) graph nodes in the graph that represent a first mesh face in a first object mesh, and (ii) a second set of (multiple) graph nodes in the graph that represent a second mesh face in a second object mesh. That is, a face-face edge can be understood as a “hyper-edge” that, rather than connecting two individual graph nodes, connects a first set of graph nodes (representing a first mesh face) to a second set of graph nodes (representing a second mesh face).

The graph generation engine 104 can generate a face-face edge for a first mesh face and a second mesh face in response to determining that the first mesh face is within a collision distance of the second mesh face, i.e., according the current environment mesh representing the current state of the environment. The graph generation engine 104 can determine that a first mesh face is within a collision distance of a second mesh face, e.g., if at least one point included in the surface defined by the first mesh face is within the collision distance of at least one point included in the surface defined by the second mesh face. Thus the face-face edges in the graph 106, if any, can be understood as representing collisions between respective mesh faces of objects in the current environment mesh. Face-face edges can represent collisions between respective mesh faces included in different objects; optionally, face-face edges can also represent collisions between non-adjacent mesh faces included in the same object mesh. It will be appreciated the face-face edges can capture and parametrize collisions that are not proximal to mesh nodes, e.g., collisions that occur on mesh faces far from mesh nodes.

Each object-node edge defines a connection between a first graph node representing an object in the environment (i.e., an object node) and a second graph node representing a mesh node. The graph generation engine 104 can define, for each object mesh in the current environment mesh, a respective object-node edge between: (i) the object node corresponding to the object, and (ii) each graph node representing a respective mesh node in the object mesh.

The graph 106 representing the current environment mesh generally includes the node-node edges representing the mesh nodes in the current environment mesh, but need not include any face-face edges or object-node edges. For instance, face-face edges can be excluded from the graph 106 if, according to the current environment mesh, none of the mesh faces are within the collision distance of one another. As another example, the inclusion of object nodes in the graph is optional, and if the set of graph nodes does not include object nodes, then the set of graph edges does not include object-node edges.

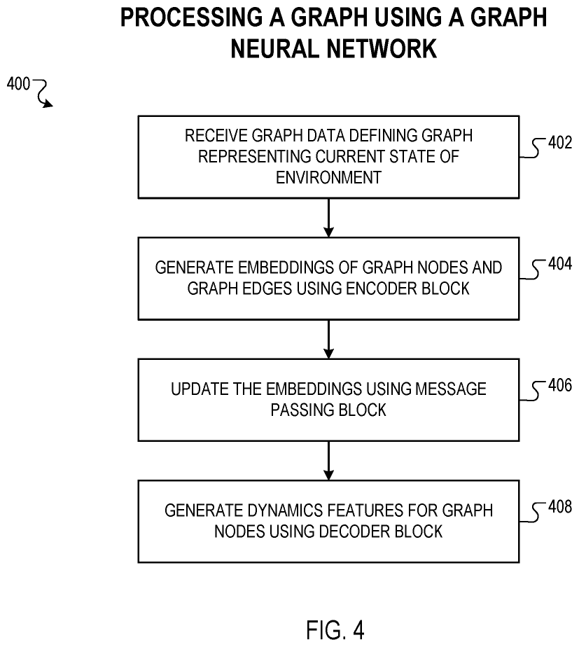

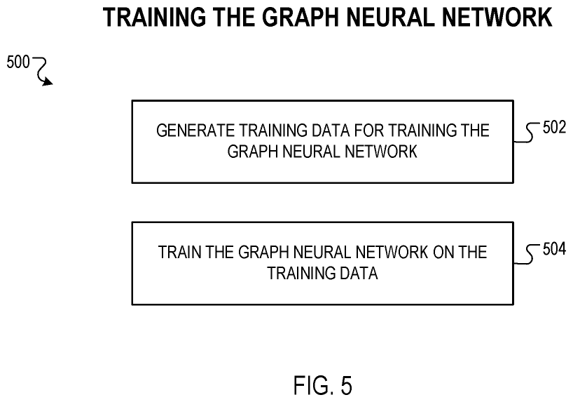

The graph neural network 108 is configured to process data defining the graph 106, in accordance with current values of a set of graph neural network parameters, to generate an updated graph 110. The updated graph 110 can have the same topology as the original graph 106, i.e., the same configuration of graph nodes and graph edges. However, each graph node of the updated graph 110 that represents a mesh node in the current environment mesh is associated with a set of one or more “dynamics features” that characterize the motion (e.g., the velocity or the acceleration) of the corresponding mesh node at the time step. As part of generating the updated graph 110, the graph neural network performs message passing operations to propagate information along the graph edges of the graph 106. Propagating information along face-face edges of the graph 106 enables the graph neural network to perform effective implicit reasoning about the effects of collisions between objects in the environment. Propagating information along object-node edges in the graph enables the graph neural network to rapidly propagate information (e.g., about collisions) between graph nodes representing mesh nodes in the same object mesh. Examples of operations that can be performed by the graph neural network 108 to generate the updated graph 110 are described in more detail with reference to FIG. 4. Example techniques for training the graph neural network are described in more detail below with reference to FIG. 5.

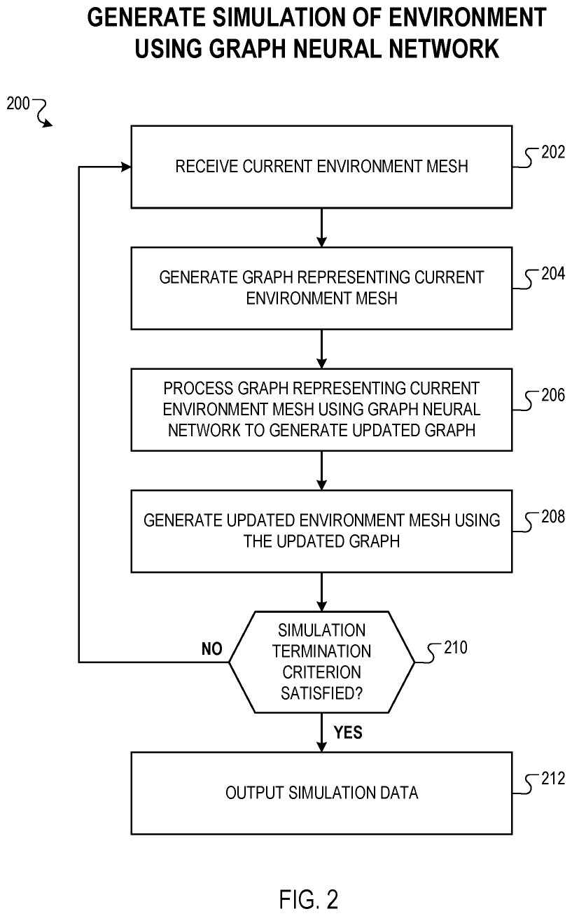

The mesh update engine 112 is configured to process the graph data defining the updated graph 110 to generate an updated environment mesh 114 that represents a (simulated) state of the environment at the next time step. Example techniques for processing the dynamics features associated with the graph nodes of the updated graph 110 to generate an updated environment mesh 114 are described in more detail with reference to FIG. 2.

The system 100 can use the graph generation engine 104, the graph neural network 108, and the mesh update engine 112 in tandem to roll out a sequence of environment meshes starting from the initial environment mesh 102. In particular, for each time step in a sequence of time steps, the system can process an environment mesh for the time step using the graph generation engine 104 to generate a corresponding graph 106; process the graph 106 using graph neural network 108 to generate an updated graph 110; and then process the updated graph 110 using the mesh update engine 112 to generate the environment mesh for the next time step. The system 100 can then output the generated sequence of environment meshes as the simulation 116 of the environment over the sequence of time steps.

The system 100 can receive the initial environment mesh 102 from any appropriate source, e.g., from a user or from an upstream system. Further, the system 100 can receive the initial environment mesh 102 in any of a variety of possible ways, e.g., through a user interface or an application programming interface (API) made available by the system 100.

In some implementations, the environment is a real-world environment, and for one or more time steps (e.g., the first time step), the system obtains the current environment mesh representing the state of the environment at the time step (e.g., the initial environment mesh 102) by obtaining sensor readings from one or more sensors in the environment, and then generating the environment mesh from the sensor readings. The one or more sensors can include, e.g., one or more lidar sensors or one or more radar sensors.

The system 100 can provide the environment simulation 116, e.g., for storage in a data storage device, or for transmission over a data communications network (e.g., the internet), or for presentation on a display of a user device (e.g., a smartphone, tablet, or personal computer). The system can store the simulation 116, e.g., by storing data defining each environment mesh included in the simulation. The system can present the simulation 116, e.g., by presenting data derived from the sequence of environment meshes of the simulation as a video, e.g., where the video may layer appropriate colors, textures, and other visual effects on the environment meshes specified by the simulation 116.

Further, the system 100 can provide the environment simulation 116 for use in one or more downstream processes. A few examples of downstream processes that can make use environment simulations 116 generated by the simulation system 100 are described next.

In some implementations, at one or more time steps, a downstream process can compare the environment mesh specified by the simulation 116 for the time step to an environment mesh generated for the time step using sensor readings from one or more sensors in the environment (e.g., lidar or radar sensors), and thus verify the simulation 116.

In some implementations, a downstream process can include designing the shape of an object included in the environment using the environment simulation 116. More specifically, the downstream process can include, at each of one or more optimization iterations: generating an initial environment mesh that includes a current object mesh for the object that defines a current shape of the object; generating a simulation 116 of the environment starting from the initial environment mesh using the simulation system 100; evaluating an objective function that depends on the simulation 116; and backpropagating gradients of the objective function through the graph neural network 108 of the simulation system 100 to adjust the current object mesh for the object. The downstream process can thus iteratively adjust the shape of the object over a sequence of optimization iterations in order to optimize the objective function. The objective function can characterize, e.g., forces or stresses experienced by the object, deformation of the object, and so forth. The downstream process can further include making (manufacturing) a physical object with the shape that optimizes the objective function. The physical object can be, e.g., a mechanical agent (e.g., a robotic agent, or a vehicle, or a watercraft, or an aircraft), machinery, equipment, tools, products, or components thereof, or any other mechanical structure.

In some implementations, a downstream process can include controlling a robot interacting with the environment. The environment may be a real-world environment. More specifically, the downstream process can include: simulating the state of the environment when the robot performs a sequence of actions over a sequence of time steps using the simulation system 100; determining that a final state of the environment at a final time step in the sequence of time steps satisfies a success criterion; and in response, causing the robot to perform the sequence of actions in the environment. The success criterion can include, e.g., that respective locations, shapes, or configurations of one or more objects in the environment are within a tolerance of one or more target locations, shapes, or configurations, or that one or more objects followed desired trajectories through the environment. The one or more objects may comprise one or more deformable objects. The one or more objects may comprise one or more components of the robot, such as a gripper. For example, the gripper may be used to grip and manipulate an object, such as a deformable object.

FIG. 2 is a flow diagram of an example process 200 for simulating the state of an environment over a sequence of time steps. For convenience, the process 200 will be described as being performed by a system of one or more computers located in one or more locations. For example, a simulation system, e.g., the simulation system 100 of FIG. 1, appropriately programmed in accordance with this specification, can perform the process 200.

The system performs steps 202-210 of the process 200 at each time step in a sequence of time steps. For convenience, the description of steps 202-210 which follows will reference a “current” time step; the current time step can be any time step in the sequence of time steps.

The system receives the current environment mesh at the current time step (202). If the current time step is the first time step, then the system can receive the current environment mesh from an external source, e.g., a user or an upstream system. If the current time step is a subsequent time step, i.e., after the first time step, then the current environment mesh can be an environment mesh that was generated by the system at the preceding time step in the sequence of time steps.

The system processes the current environment mesh to generate graph data that defines a graph representing the state of the environment at the current time step (204). The graph can, at some or all time steps, include face-face edges that represent collisions between mesh faces of respective object meshes. An example process for generating the graph representing the state of the environment at the current time step is described in more detail with reference to FIG. 3.

The system processes the graph data defining the graph representing the state of the environment at the current time step using a graph neural network to generate an updated graph (206). The graph nodes of the updated graph that represent mesh nodes in the current environment mesh can be can be associated with dynamics features that characterize motion (e.g., velocity or acceleration) of the mesh nodes at the current time step.

The system generates an updated environment mesh representing the state of the environment at the next time step using the updated graph (208). For instance, for each mesh node in the mesh, the system can determine the position

$${x}_{i}^{t + 1}$$

of mesh node i at the next time step (t+1) as:

$${x}_{i}^{t + 1} = {a}_{i} + 2 {x}_{i}^{t} - {x}_{i}^{t - 1} \qquad ( 1 )$$

where aᵢ is the acceleration of mesh node i at the current time step,

$${x}_{i}^{t}$$

is the position of mesh node i at the current time step, and

$${x}_{i}^{t - 1}$$

is the position of mesh node i at the preceding time step. In example, the accelerations {aᵢ}ᵢ of the mesh nodes are included in the dynamics features associated with the graph nodes in the updated graph generated by the graph neural network.

Optionally, the system can perform various post-processing operations on the updated environment mesh prior to providing the updated environment mesh for processing at the next time step (or outputting the updated environment mesh as part of the simulation of the environment). For instance, if the updated environment mesh includes an object mesh representing a rigid object, i.e., an object having a predefined shape that should not change between time steps, then the system can adjust the object mesh representing the object in the updated environment mesh to cause the object mesh to maintain the predefined shape.

The system determines whether a simulation termination criterion is satisfied at the current time step (210). The system can determine that a simulation criterion is satisfied, e.g., if the current time step is a predefined final time step in the sequence of time steps, or if the state of the environment has transitioned into a predefined goal state. The goal state can characterize, e.g., respective goal locations, shapes, or configurations of one or more objects in the environment.

In response to determining that a simulation termination is not satisfied, the system provides the updated environment mesh as the current environment mesh for the next time step and returns to step 202.

In response to determining that a simulation termination criterion is satisfied, the system outputs simulation data that includes a respective environment mesh for each time step in the sequence of time steps (212).

FIG. 3 is a flow diagram of an example process 300 for processing a current environment mesh to generate a graph representing the current state of the environment at a time step. For convenience, the process 300 will be described as being performed by a system of one or more computers located in one or more locations. For example, a simulation system, e.g., the simulation system 100 of FIG. 1, appropriately programmed in accordance with this specification, can perform the process 300.

The system receives a current environment mesh representing the state of the environment at the current time step (302).

The system processes the current environment mesh to generate data defining a set of graph nodes of the graph (304). The system also generates a set of graph node features for each graph node in the graph.

To generate the set of graph nodes, the system instantiates a respective graph node representing each mesh node in current environment mesh. For each graph node that represents a mesh node, the system can generate a set of graph node features

$${v}_{i}^{M}$$

for the graph node as:

$${v}_{i}^{M} = [ {x}_{i}^{t} - {x}_{i}^{t - 1} , … , {x}_{i}^{t - h + 1} - {x}_{i}^{t - h} , {p}_{i} , {k}_{i} , {f}_{i}^{t} ] \qquad ( 2 )$$

where

$${x}_{i}^{s}$$

denotes the position of the mesh node at time step s, pᵢ represents static object properties, kᵢ is a binary kinematic feature that indicates whether the mesh node is subject to dynamics (e.g., as a moving object) or has a static position (e.g., as part of a static surface), h is a history length (e.g., a predefined number of previous time steps to be used for generating the graph node features at the current time step), and

$${f}_{i}^{t}$$

is a feature that characterizes how much the mesh node can move at the next time step.

Optionally, the system can also generate a respective object-level node (“object node”) representing each of one or more objects in the environment. For each object node, the system can generate a set of graph node features for the object node as described in equation (2) above, where the “position” of the object node at each time step can be defined as the center of mass of the object represented by the object node.

The system processes the current environment mesh to generate data defining a set of graph edges of the graph (306). The system also generates a set of graph edge features for each graph edge in the graph.

To generate the set of graph edges, the system instantiates a respective “node-node” graph edge representing each mesh node in the mesh. For each node-node graph edge, the system can generate a set of graph edge features

$${e}_{i}^{M}$$

for the graph edge as:

$${e}_{i}^{M} = [ {d}_{rs} , {d}_{rs}^{U} ] \qquad ( 3 )$$

where dᵣₛ is a vector of position differences between the mesh nodes connected by the mesh edge in the current environment mesh, and

$${d}_{rs}^{U}$$

is a vector of position differences between the mesh nodes connected by the mesh edge in a reference environment mesh that is static and independent of the simulation dynamics.

Further, as part of generating the set of graph edges, the system determines whether any faces of object meshes in the environment mesh are within a pre-determined distance, referred to herein as a collision distance of one another. In response to determining that a first face of a first object mesh is within the collision distance of a second face of a second object mesh, the system instantiates a corresponding “face-face” edge in the graph. The face-face edge connects: (i) a first set of graph nodes in the graph that represent the first face in the first object mesh, and (ii) a second set of graph nodes in the graph that represent the second face in the second object mesh. For instance, if the current environment mesh is a triangular mesh, then the face-face edge connects three graph nodes representing the triangular first mesh face to three graph nodes representing the triangular second mesh face.

The system can determine that a first mesh face is within a collision distance of a second mesh face, e.g., if at least one point included in the surface defined by the first mesh face is within the collision distance of at least one point included in the surface defined by the second mesh face. The system can use any appropriate algorithm, e.g., the Bounding Volume Hierarchy (BVH) algorithm, to identify all pairs of mesh faces from different objects that are within the collision distance.

For each face-face edge in the graph, the system can generate a set of graph edge features for the face-face edge. In particular, for a face-face edge corresponding to a first mesh face and a second mesh face, the system can identify: (i) a first point in the first mesh face, and (ii) a second point in the second mesh face, that are separated by a minimal distance between the first mesh face and the second mesh face. The system can then generate a set of graph edge features for the face-face edge with reference to the first point in the first mesh face and the second point in the second mesh face. For instance, the system can generate graph edge features for the face-face edge based on a relative vector between the first point and the second point. As another example, the system can generate graph edge features for the face-face edge by generating, for each mesh node in the first mesh face, a feature based on a relative vector between: (i) the mesh node in the first mesh face, and (ii) the first point. As another example, the system can generate graph edge features for the face-face edge by generating, for each mesh node in the second mesh face, a feature based on a relative vector between: (i) the mesh node in the second mesh face, and (ii) the second point.

As an alternative to or in combination with the graph edge features described above, the system can generate any of a variety of other graph edge features for face-face edges. For instance, the system can generate graph edge features for a face-face edge based on a normal vector to the first mesh face in the first object mesh and a normal vector the second mesh face in the second object mesh.

Further, for each object node in the set of graph nodes, the system can generate a respective “object-node” edge between: (i) the object node, and (ii) each graph node representing a mesh node of an object mesh representing the corresponding object. For each object-node graph edge, the system can generate a set of graph edge features

$${e}_{i}^{O}$$

for the graphedge as:

$${e}_{i}^{O} = [ {d}_{rs}^{O} , {d}_{rs}^{O , U} ] \qquad ( 4 )$$

where

$${d}_{rs}^{O}$$

is a vector of position differences between the mesh node and the object node in the current environment mesh, and

$${d}_{rs}^{O , U}$$

is a vector of position differences between the mesh node and the object node in a reference environment mesh that is static and independent of the simulation dynamics. The position of the object node can be defined, e.g., as the center (e.g., center of mass) of the corresponding object, as described above.

The system can instantiate the edges in the graph as unidirectional edges, bidirected edges, undirected edges, or a combination thereof. In implementations, where the system determines than unidirectional edges should connect a first node and a second node, the system can optionally instantiate symmetric unidirectional edges: a first unidirectional edge from the first node to the second node, and a second unidirectional edge from the second node to the first node.

The system outputs the graph that represents the current state of the environment (308). For instance, the system can provide the graph for processing by a graph neural network, as will be described next with reference to FIG. 4.

FIG. 4 is a flow diagram of an example process 400 for processing a graph representing the current state of the environment using a graph neural network to generate an updated graph. For convenience, the process 400 will be described as being performed by a system of one or more computers located in one or more locations. For example, a simulation system, e.g., the simulation system 100 of FIG. 1, appropriately programmed in accordance with this specification, can perform the process 400.

The system receives graph data defining the graph representing the current state of the environment (402).

The system generates a respective embedding of each graph node and each graph edge in the graph using an encoder block the graph neural network (404). For instance, for each graph node that represents a mesh node in the current environment mesh, the system can process the graph node features of the graph node using a mesh node embedding subnetwork included in the encoder block to generate the embedding of the graph node. As another example, for each graph node that represents an object node, the system can process the graph node features of the graph node using an object node embedding subnetwork included in the encoder block to generate the embedding of the graph node. As another example, for each node-node graph edge, the system can process the graph edge features of the graph edge using a node-node edge embedding subnetwork included in the encoder neural network to generate the embedding of the node-node edge. As another example, for each face-face graph edge, the system can process the graph edge features of the graph edge using a face-face edge embedding subnetwork to generate the embedding of the face-face edge. As another example, for each object-node edge, the system can process the graph edge features of the graph edge using an object-node embedding subnetwork to generate the embedding of the object-node edge.

The system iteratively updates the embeddings of the graph nodes and the graph edges over a sequence of update iterations using a sequence of message passing blocks of the graph neural network (406). In particular, each message passing block can be configured to process the embeddings of the graph nodes and the graph edges to update the embeddings of the graph nodes and the graph edges by operations that are parametrized by a set of message passing block parameters and are conditioned on the topology of the graph. The graph neural network can include any appropriate number of message passing blocks, e.g., 2 message passing blocks, or 10 message passing blocks, or 50 message passing blocks. The message passing blocks can, but are not required to, share the same message passing block parameters.

Each message passing block can including an edge updating subnetwork for updating the embeddings of face-face edges in the graph. More specifically, for a face-face edge connecting a first mesh face and a second mesh face, the edge updating subnetwork can be configured to process: (i) the embedding of the face-face edge, (ii) a respective node embedding for each graph node representing a mesh node in the first mesh face, and (ii) a respective node embedding for each graph node representing a mesh node in the second mesh face, to generate an updated embedding for the face-face edge. For instance, the edge updating subnetwork can be configured to generate an updated embedding Q′ for the face-face edge as:

$${Q}^{′} = MLP ( [ {[ {q}_{j} , {v}_{{s}_{j}} , {v}_{{r}_{j}} ]}_{j = 1 , 2 , 3} ] ) \qquad ( 5 )$$

where MLP(⋅) refers to a multi-layer perceptron (fully connected neural network), [qⱼ]ⱼ₌₁₂₃ refers to the embedding of the face-face edge (which includes three respective sub-embeddings),

$${[ {v}_{{s}_{j}} ]}_{j = 1 , 2 , 3}$$

are the node embeddings for the graph nodes representing mesh nodes in the first mesh face, and

$${[ {v}_{{r}_{j}} ]}_{j = 1 , 2 , 3}$$

are the node embeddings for the graph nodes representing mesh nodes in the second mesh face.

Each message passing block can further include one or more edge updating subnetwork for updating the embeddings of node-node edges and object-node edges. More specifically, for a node-node edge or an object-node edge connecting a first graph node and a second graph node, an edge updating subnetwork can be configured to process: (i) the embedding of the edge, (ii) the embedding of the first graph node, and (ii) the embedding of the second graph node, to generate an updated embedding for the graph edge. In some cases each message passing block includes respective (different) edge updating subnetworks for node-node edges and object-node edges.

Each message passing block can further include a node updating subnetwork for updating the embeddings of object nodes. More specifically, for each object node, the node updating subnetwork for object nodes can be configured to process: (i) the embedding of the object node, and (ii) the embeddings of each graph edge that connects to the object node, to generate an updated embedding for the object node.

In a perfect rigid object, information propagates across the rigid object at infinite speed. However, with n update iterations, information can only propagate for n hops, and for a very fine mesh when a collision happens it may take many message passing steps to reach all other nodes in the mesh. The object nodes facilitate long-range communication by causing any two mesh nodes in an object to be separated by at most two hops, and thus decoupling the dynamics from the mesh complexity as collision events can be computed on local neighborhoods using local message passing and the resulting collision impulses can be aggregated and broadcast across the object using the object node.

Each message passing block can further include a node updating subnetwork for updating the embeddings of graph nodes representing mesh nodes. More specifically, for each graph node representing a mesh node, the node updating subnetwork can be configured to process: (i) the embedding of the graph node, (ii) the embeddings of node-node edges and object-node edges connected to the graph node, and (iii) at least a portion of the embedding of any face-face edge connected to a mesh face that includes the mesh node, to generate an updated embedding for the graph node. In some cases, the edge embedding of a face-face edge can be associated with a partition into a number of sub-embeddings equal to the number of mesh nodes included in the mesh face, and each sub-embedding can be assigned to a respective mesh node included in the mesh face. In these cases, the input to the node updating subnetwork may include only the sub-embedding assigned to mesh node represented by the graph node.

The system can define a partition of an embedding of a face-face edge, e.g., by dividing the embedding of the face-face edge into an ordered sequence of equally-sized sub-embeddings, where the number of sub-embeddings is equal to the number of mesh nodes in a mesh face. The system can define an assignment of the sub-embeddings to the mesh nodes in a mesh face connected to by the face-face edge, e.g., by defining an ordering of the mesh nodes in the mesh face, and then assigning each sub-embedding to a corresponding mesh node based on the ordering.

For a face-face edge that connects a first mesh face to a second mesh face, the system can define an ordering of the mesh nodes included in the first mesh face and the mesh nodes included in the second mesh face. For instance, the system can identify a first point on the first mesh face and a second point on the second mesh face that are separated by a minimal distance (i.e., from among pairs of points drawn from the two mesh faces). The system can define an ordering of the mesh nodes included in the first mesh face based on their proximity to the first point in the first mesh face. Similarly, the system can define an ordering of the mesh nodes included in the second mesh face based on their proximity to the second point in the second mesh face.

In some implementations, the node updating subnetwork for updating the embeddings of graph nodes representing mesh nodes can be configured to generate an updated embedding

$${v}_{i}^{′}$$

for a graph node representing a mesh node as:

$${v}_{i}^{′} = MLP ( [ {v}_{i} , {\sum }_{( for every {e}_{{v}_{s} \to {v}_{r}} \vert {v}_{r} = {v}_{i} )} {e}_{{v}_{s} \to {v}_{r}}^{′} , {\sum }_{for every {q}_{{ℱ}_{s} \to {ℱ}_{r}} \vert {ℱ}_{r} [ j ] = {v}_{i}} {q}_{j , {ℱ}_{s} \to {ℱ}_{r}} ] ) \qquad ( 6 )$$

where MLP(⋅) refers to a multi-layer perceptron (fully connected neural network), vi denotes the embedding of the graph node prior to being updated, the first sum is over the set of embeddings of node-node edges and object-node edges that connect to the graph node, and the second sum is over the set of face-face edges (if any) that connected to the mesh face that includes the mesh node, where [symbol] is a sub-embedding that is included in the embedding of the face-face edge and that corresponds to the graph node.

After iteratively updating the embeddings of the graph nodes and the graph edges using the sequence of message passing blocks, the system generates one or more respective dynamics features for each graph node that represents a mesh node using a decoder block of the graph neural network (408). The dynamics features for a graph node can characterize the motion of the corresponding mesh node, e.g., the velocity or acceleration of the mesh node. For each graph node representing a mesh node, the decoder block can process the updated node embedding for the graph node (e.g., that was generated by the last message passing block) to generate the one or more dynamics features for the graph node.

The graph neural network and its constituent parts (e.g., the encoder block, the message passing blocks, and the decoder block) can have any appropriate neural network architectures that enable them to perform their described functions. For instance, the graph neural network and its constituent parts can each include any appropriate types of neural network layers (e.g., fully-connected layers, convolutional layers, attention layers, and so forth) in any appropriate number (e.g., 5 layers, or 10 layers, or 50 layers) and connected in any appropriate configuration (e.g., as a directed graph of layers).

FIG. 5 is a flow diagram of an example process 500 for training a graph neural network. For convenience, the process 500 will be described as being performed by a system of one or more computers located in one or more locations. For example, a simulation system, e.g., the simulation system 100 of FIG. 1, appropriately programmed in accordance with this specification, can perform the process 500.

The system generates training data for training the graph neural network (502). The training data includes a set of training examples. Each training example includes: (i) a training input to the graph neural network, and (ii) a target output of the graph neural network. The training input to the graph neural network can include graph data, derived from an environment mesh, that defines a training graph representing the state of a training environment at a time step. The target output of the graph neural network can define, for each graph node of the training graph that represents a mesh node of the environment mesh, target dynamics features characterizing motion (e.g., velocity or acceleration) of the mesh node at the time step. The system can generate the training examples in any of a variety of ways. For instance, the system can generate a training simulation of a training environment over a sequence of time steps using an analytical (e.g., physics-based) simulator. The system can then generate a respective training example for each of one or more time steps of the training simulation. The training data may be generated in any other appropriate manner e.g. from captured real-world data. Optionally, the system can add random noise to the training inputs and target outputs of the training examples in order to increase the robustness of the trained graph neural network.

The system trains the graph neural network on the training data (504). In particular, for each training example, the system trains the graph neural network to reduce a discrepancy between: (i) a predicted output generated by the graph neural network by processing the training input of the training example, and (ii) the target output of the training example. In particular, for each training example, the system can determine gradients (with respect to the parameters of the graph neural network) of an objective function that measures an error between: (i) the predicted output, and (ii) the targe output, for the training example. The system can the use the gradients to update the current parameter values of the set of parameters of the graph neural network using the update rule of an appropriate gradient descent optimization algorithm. The system can determine the gradients, e.g., using backpropagation, and the gradient descent optimization algorithm can be, e.g., RMSprop or Adam.

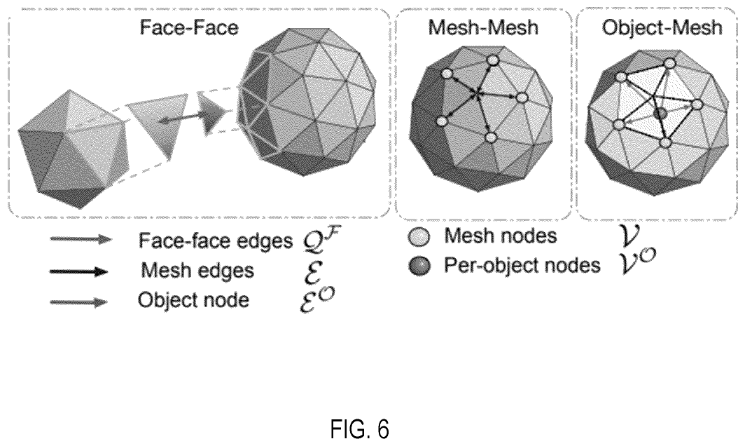

FIG. 6 provides an illustration of face-face edges, mesh edges, object nodes, mesh modes, and object-level nodes.

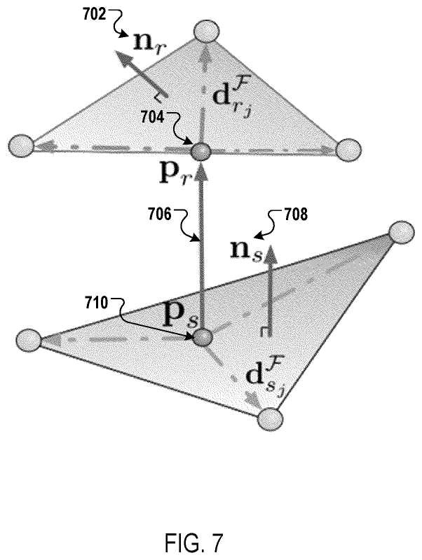

FIG. 7 provides an illustration of the features that can be computed for a face-face edge that connects a first mesh face and a second mesh face. As part of computing the features of the face-face edge, the simulation system can identify a first point 704 on the first mesh face and a second point 710 on the second mesh face that are separated by a minimal distance. The simulation system can then determine the features of the face-face edge at least partially with reference to the first point and the second point. For instance, the set of face-face features can include a vector 706 between the first point and the second point, respective vectors between the first point and each mesh node in the first mesh face, and respective vectors between the second point and each mesh node in the second mesh face. The features of the face-face edge can additionally include, e.g., a normal vector 702 to the first mesh surface and a normal vector 708 to the second mesh surface.

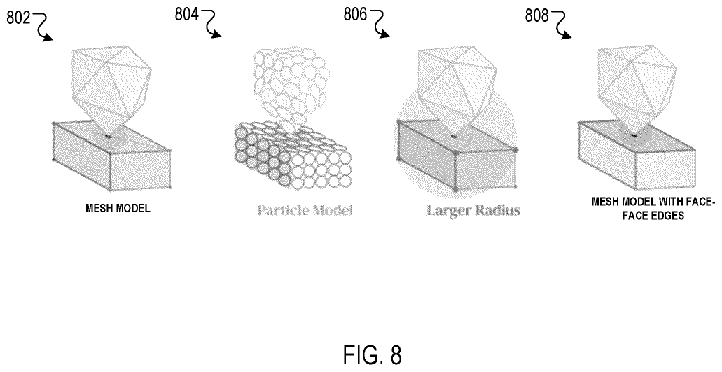

FIG. 8 illustrates how various simulation models treat colliding objects. In a mesh-based model without face-face edges (802), a collision where a mesh node of one object intersects with the mesh surface of another object may be undetected for small collision distances. In a particle model (804), i.e., where objects are represented as dense particle clouds, detecting collisions requires evaluating and processing distances between large numbers of particles. In a mesh-based model with a large collision radius (806), collisions are more likely to be detected but the number of edges increases quadratically with the collision radius. In a mesh-based model with face-face edges (808), as described in this specification, collisions can be accurately and efficiently modeled using sparse mesh representations.

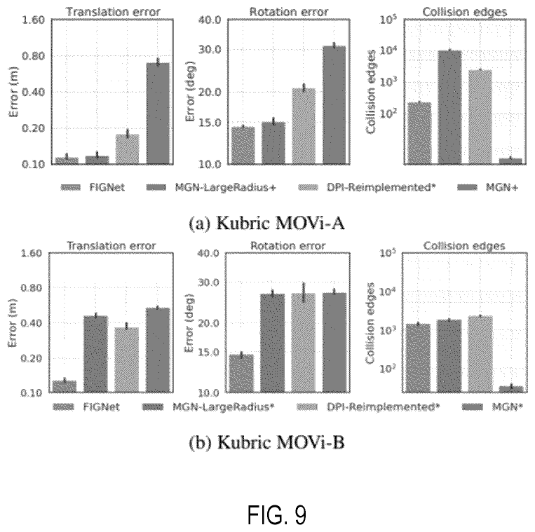

FIG. 9 shows experimental results comparing the performance of a particular implementation of the simulation system described in this specification (labeled as “FIGNet”) with other simulation systems (labeled as “MGN-LargeRadius+”, “DPI-Reimplemented”, and “MGN+”) when evaluated on two different datasets (labeled as “Kubric MOVi-A” and “Kubric MOVi-B”). The results show the translation error and the rotation errors achieved by each model, as well as the number of collision edges computed by each model. It will be appreciated that the simulation system described in this specification achieves lower translation and rotation errors than the alternative systems, and requires computing fewer collision edges than several of the alternative systems.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

In this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework, or a Jax framework.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

Aspects of the present disclosure may be as set out in the following numbered examples:

Example 1. A method performed by one or more computers for simulating a state of an environment over a sequence of time steps, the method comprising, at each of one or more time steps: obtaining an environment mesh representing the state of the environment at the time step, wherein environment mesh includes: (i) a first object mesh representing a first object in the environment, and (ii) a second object mesh representing a second object in the environment; generating a graph representing the state of the environment at the time step, wherein the graph comprises a plurality of graph nodes and a plurality of graph edges, and wherein generating the graph comprises: determining that a first face of the first object mesh is within a collision distance of a second face of the second object mesh; and in response, instantiating a face-face edge in the graph, wherein the face-face edge is a graph edge that connects: (i) a first set of graph nodes in the graph that represent the first face in the first object mesh, and (ii) a second set of graph nodes in the graph that represent the second face in the second object mesh; processing the graph using a graph neural network to generate an updated graph; and generating an updated environment mesh representing the state of the environment at a next time step using the updated graph.

Example 2. The method of example 1, wherein generating the graph representing the state of the environment at the time step comprises: generating a respective edge embedding for each of the plurality of graph edges; and generating a respective node embedding for each of the plurality of graph nodes.

Example 3. The method of example 2, wherein generating a respective edge embedding for each of the plurality of graph edges comprises generating an edge embedding for the face-face edge, comprising: determining a set of features characterizing: (i) the first face in the first object mesh, and (ii) the second face in the second object mesh; and generating the edge embedding for the face-face edge based on the set of features characterizing: (i) the first face in the first object mesh, and (ii) the second face in the second object mesh.

Example 4. The method of example 3, wherein determining the set of features characterizing: (i) the first face in the first object mesh, and (ii) the second face in the second object mesh comprises: identifying: (i) a first point in the first face in the first object mesh, and (ii) a second point in the second face in the second object mesh, that are separated by a minimal distance between the first face and the second face; and generating one or more features with reference to the first point and the second point.

Example 5. The method of example 4, wherein generating one or more features with reference to the first point and the second point comprises: generating a feature based on a relative vector between the first point and the second point.

Example 6. The method of any one of examples 4-5, wherein generating one or more features with reference to the first point and the second point comprises: generating, for each graph node representing a mesh node in the first face, a feature based on a relative vector between: (i) the mesh node in the first face, and (ii) the first point; and generating, for each graph node representing a mesh node in the second face, a feature based on a relative vector between: (i) the mesh node in the second face, and (ii) the second point.

Example 7. The method of any one of examples 3-6, wherein determining the set of features characterizing: (i) the first face in the first object mesh, and (ii) the second face in the second object mesh comprises: generating features based on: (i) a normal vector to the first face in the first object mesh, and (ii) a normal vector to the second face in the second object mesh.

Example 8. The method of any one of examples 3-7, wherein generating the edge embedding for the face-face edge based on the set of features characterizing: (i) the first face in the first object mesh, and (ii) the second face in the second object mesh, comprises: processing the set of features characterizing: (i) the first face in the first object mesh, and (ii) the second face in the second object mesh, using a face-face edge embedding subnetwork to generate the edge embedding for the face-face edge.

Example 9. The method of any one of examples 2-8, wherein processing the graph using the graph neural network to generate the updated graph comprises, at each of a sequence of update iterations: updating the respective edge embedding for each of the plurality of graph edges using the graph neural network; and updating the respective node embedding for each of the plurality of graph nodes using the graph neural network.

Example 10. The method of example 9, wherein at each update iteration, updating the respective edge embedding for each of the plurality of graph edges comprises, for each graph edge: processing a network input characterizing the graph edge using an edge updating subnetwork of the graph neural network to generate an updated edge embedding for the graph edge.

Example 11. The method of example 10, wherein for the face-face edge, the network input processed by the edge updating subnetwork of the graph neural network comprises: the edge embedding for the face-face edge; a respective node embedding for each graph node representing a mesh node in the first face in the first object mesh; and a respective node embedding for each graph node representing a mesh node in the second face in the second object mesh.

Example 12. The method of any one of examples 9-11, wherein at each update iteration, updating the respective node embedding for each of the plurality of graph nodes comprises, for each graph node: processing a network input characterizing the graph node using a node updating subnetwork of the graph neural network to generate an updated node embedding for the graph node.

Example 13. The method of example 12, wherein for each graph node that represents: (i) a mesh node of the first face in the first object mesh, or (ii) a mesh node of the second face in the second object mesh, the network input characterizing the graph node that is processed by the node updating subnetwork of the graph neural network comprises: the node embedding for the graph node; and at least a portion of the edge embedding for the face-face edge.

Example 14. The method of example 13, wherein the edge embedding for the face-face edge is associated with a partition into a plurality of sub-embeddings, wherein one of the sub-embeddings is assigned to the graph node, and wherein the network input characterizing the graph node that is processed by the node updating subnetwork of the graph neural network comprises only the sub-embedding that is assigned to the graph node.

Example 15. The method of any one of examples 13-14, wherein the network input characterizing the graph node that is processed by the node updating subnetwork of the graph neural network further comprises: a respective edge embedding for each node-node edge in the graph that connects the graph node to another graph node.

Example 16. The method of any preceding example, wherein generating the graph representing the state of the environment at the time step comprises, for each of one or more objects in the environment: instantiating an object node in the graph, wherein the object node corresponds to the object; and instantiating a respective edge between the object node and each graph node representing a mesh node of an object mesh representing the object.

Example 17. The method of example 16, wherein for each of the one or more objects in the environment, the object node corresponding to the object in the graph is associated with a spatial position at a center of the object.

Example 18. The method of any one of examples 9-17, wherein generating the updated environment mesh representing the state of the environment at the next time step using the updated graph comprises, for each graph node that represents a corresponding mesh node in the mesh: processing an updated node embedding of the graph node in the updated graph to generate a dynamics feature for the corresponding mesh node; and determining a position of the corresponding mesh node at the next time step using the dynamics feature for the corresponding mesh node.

Example 19. The method of any preceding example, wherein the one or more computers that perform the method include one or more hardware accelerator units; wherein processing the graph using the graph neural network to generate the updated graph comprises updating the graph at each of one or more update iterations using a processor system comprising L message passing blocks, wherein each message passing block has a same neural network architecture and a separate set of neural network parameters; the method further comprising: applying the message passing blocks sequentially to process data defining the graph over multiple iterations; and using the one or more hardware accelerator units to apply the message passing blocks sequentially to process the data defining the graph.

Example 20. The method of example 19, wherein the one or more computers that perform the method include multiple hardware accelerators, and wherein the method comprises distributing the processing using the message passing blocks over the hardware accelerators.

Example 21. The method of any preceding example, wherein the environment comprises a real-world environment; wherein at one or more time steps, obtaining the environment mesh representing the state of the environment at the time step comprises: obtaining sensor readings from one or more sensors in the environment; and generating the environment mesh from the sensor readings.

Example 22. The method of example 21, wherein the one or more sensors include one or more lidar or radar sensors.

Example 23. The method of any one of examples 21-22, further comprising, at one or more time steps: comparing an environment mesh for the time step generated using the graph neural network to an environment mesh generated for the time step using sensor readings from one or more sensors in the environment to verify the simulation of the state of the environment.

Example 24. A method of designing a shape of the first object using the method of any preceding example, wherein the method of designing the shape of the first object comprises backpropagating gradients of an objective function through the graph neural network to adjust data representing the shape of the first object to determine a shape of the first object that optimizes an objective function.

Example 25. The method of example 24, further comprising making a physical object with the shape that optimizes the objective function.

Example 26. A method of controlling a robot interacting with the environment, the method comprising: simulating the state of the environment when the robot performs a sequence of actions over a sequence of time steps using the method of any one of examples 1-23; determining that a final state of the environment at a final time step in the sequence of time steps satisfies a success criterion; and in response, causing the robot to perform the sequence of actions in the environment.

Example 27. The method of example 26, wherein determining that the final state of the environment at the final time step in the sequence of time steps satisfies the success criterion comprises: determining that respective locations, shapes, or configurations of the first object and the second object are within a tolerance of one or more target locations, shapes, or configurations of the first object and the second object.

Example 28. A system comprising: one or more computers; and one or more storage devices communicatively coupled to the one or more computers, wherein the one or more storage devices store instructions that, when executed by the one or more computers, cause the one or more computers to perform operations of the respective method of any one of examples 1-24 or 26-27.

Example 29. One or more non-transitory computer storage media storing instructions that when executed by one or more computers cause the one or more computers to perform operations of the respective method of any one of examples 1-24 or 26-27.

What is claimed is:

1. A method performed by one or more computers for simulating a state of an environment over a sequence of time steps, the method comprising, at each of one or more time steps:
obtaining an environment mesh representing the state of the environment at the time step, wherein environment mesh includes: (i) a first object mesh representing a first object in the environment, and (ii) a second object mesh representing a second object in the environment;
generating a graph representing the state of the environment at the time step, wherein the graph comprises a plurality of graph nodes and a plurality of graph edges, and wherein generating the graph comprises:
determining that a first face of the first object mesh is within a collision distance of a second face of the second object mesh; and
in response, instantiating a face-face edge in the graph, wherein the face-face edge is a graph edge that connects: (i) a first set of graph nodes in the graph that represent the first face in the first object mesh, and (ii) a second set of graph nodes in the graph that represent the second face in the second object mesh;
processing the graph using a graph neural network to generate an updated graph; and
generating an updated environment mesh representing the state of the environment at a next time step using the updated graph.

2. The method of claim 1, wherein generating the graph representing the state of the environment at the time step comprises:
generating a respective edge embedding for each of the plurality of graph edges; and
generating a respective node embedding for each of the plurality of graph nodes.

3. The method of claim 2, wherein generating a respective edge embedding for each of the plurality of graph edges comprises generating an edge embedding for the face-face edge, comprising:
determining a set of features characterizing: (i) the first face in the first object mesh, and (ii) the second face in the second object mesh; and
generating the edge embedding for the face-face edge based on the set of features characterizing: (i) the first face in the first object mesh, and (ii) the second face in the second object mesh.

4. The method of claim 3, wherein determining the set of features characterizing: (i) the first face in the first object mesh, and (ii) the second face in the second object mesh comprises:
identifying: (i) a first point in the first face in the first object mesh, and (ii) a second point in the second face in the second object mesh, that are separated by a minimal distance between the first face and the second face; and
generating one or more features with reference to the first point and the second point.

5. The method of claim 4, wherein generating one or more features with reference to the first point and the second point comprises:
generating a feature based on a relative vector between the first point and the second point.

6. The method of claim 4, wherein generating one or more features with reference to the first point and the second point comprises:
generating, for each graph node representing a mesh node in the first face, a feature based on a relative vector between: (i) the mesh node in the first face, and (ii) the first point; and
generating, for each graph node representing a mesh node in the second face, a feature based on a relative vector between: (i) the mesh node in the second face, and (ii) the second point.

7. The method of claim 3, wherein determining the set of features characterizing: (i) the first face in the first object mesh, and (ii) the second face in the second object mesh comprises:
generating features based on: (i) a normal vector to the first face in the first object mesh, and (ii) a normal vector to the second face in the second object mesh.

8. The method of claim 3, wherein generating the edge embedding for the face-face edge based on the set of features characterizing: (i) the first face in the first object mesh, and (ii) the second face in the second object mesh, comprises:
processing the set of features characterizing: (i) the first face in the first object mesh, and (ii) the second face in the second object mesh, using a face-face edge embedding subnetwork to generate the edge embedding for the face-face edge.

9. The method of claim 2, wherein processing the graph using the graph neural network to generate the updated graph comprises, at each of a sequence of update iterations:
updating the respective edge embedding for each of the plurality of graph edges using the graph neural network; and
updating the respective node embedding for each of the plurality of graph nodes using the graph neural network.

10. The method of claim 9, wherein at each update iteration, updating the respective edge embedding for each of the plurality of graph edges comprises, for each graph edge:
processing a network input characterizing the graph edge using an edge updating subnetwork of the graph neural network to generate an updated edge embedding for the graph edge.

11. The method of claim 10, wherein for the face-face edge, the network input processed by the edge updating subnetwork of the graph neural network comprises:
the edge embedding for the face-face edge;
a respective node embedding for each graph node representing a mesh node in the first face in the first object mesh; and
a respective node embedding for each graph node representing a mesh node in the second face in the second object mesh.

12. The method of claim 9, wherein at each update iteration, updating the respective node embedding for each of the plurality of graph nodes comprises, for each graph node:
processing a network input characterizing the graph node using a node updating subnetwork of the graph neural network to generate an updated node embedding for the graph node.

13. The method of claim 12, wherein for each graph node that represents: (i) a mesh node of the first face in the first object mesh, or (ii) a mesh node of the second face in the second object mesh, the network input characterizing the graph node that is processed by the node updating subnetwork of the graph neural network comprises:
the node embedding for the graph node; and
at least a portion of the edge embedding for the face-face edge.

14. The method of claim 13, wherein the edge embedding for the face-face edge is associated with a partition into a plurality of sub-embeddings,
wherein one of the sub-embeddings is assigned to the graph node, and
wherein the network input characterizing the graph node that is processed by the node updating subnetwork of the graph neural network comprises only the sub-embedding that is assigned to the graph node.

15. The method of claim 13, wherein the network input characterizing the graph node that is processed by the node updating subnetwork of the graph neural network further comprises:
a respective edge embedding for each node-node edge in the graph that connects the graph node to another graph node.

16. The method of claim 1, wherein generating the graph representing the state of the environment at the time step comprises, for each of one or more objects in the environment:
instantiating an object node in the graph, wherein the object node corresponds to the object; and
instantiating a respective edge between the object node and each graph node representing a mesh node of an object mesh representing the object.

17. The method of claim 16, wherein for each of the one or more objects in the environment, the object node corresponding to the object in the graph is associated with a spatial position at a center of the object.

18. The method of claim 9, wherein generating the updated environment mesh representing the state of the environment at the next time step using the updated graph comprises, for each graph node that represents a corresponding mesh node in the mesh:
processing an updated node embedding of the graph node in the updated graph to generate a dynamics feature for the corresponding mesh node; and
determining a position of the corresponding mesh node at the next time step using the dynamics feature for the corresponding mesh node.

19. (canceled)

20. (canceled)

21. (canceled)

22. (canceled)

23. (canceled)

24. (canceled)

25. (canceled)

26. (canceled)

27. (canceled)

28. A system comprising:
one or more computers; and
one or more storage devices communicatively coupled to the one or more computers, wherein the one or more storage devices store instructions that, when executed by the one or more computers, cause the one or more computers to perform operations for simulating a state of an environment over a sequence of time steps, the operations comprising, at each of one or more time steps:
obtaining an environment mesh representing the state of the environment at the time step, wherein environment mesh includes: (i) a first object mesh representing a first object in the environment, and (ii) a second object mesh representing a second object in the environment;
generating a graph representing the state of the environment at the time step, wherein the graph comprises a plurality of graph nodes and a plurality of graph edges, and wherein generating the graph comprises:
determining that a first face of the first object mesh is within a collision distance of a second face of the second object mesh; and
in response, instantiating a face-face edge in the graph, wherein the face-face edge is a graph edge that connects: (i) a first set of graph nodes in the graph that represent the first face in the first object mesh, and (ii) a second set of graph nodes in the graph that represent the second face in the second object mesh;
processing the graph using a graph neural network to generate an updated graph; and
generating an updated environment mesh representing the state of the environment at a next time step using the updated graph.

29. One or more non-transitory computer storage media storing instructions that when executed by one or more computers cause the one or more computers to perform operations for simulating a state of an environment over a sequence of time steps, the operations comprising, at each of one or more time steps:
obtaining an environment mesh representing the state of the environment at the time step, wherein environment mesh includes: (i) a first object mesh representing a first object in the environment, and (ii) a second object mesh representing a second object in the environment;
generating a graph representing the state of the environment at the time step, wherein the graph comprises a plurality of graph nodes and a plurality of graph edges, and wherein generating the graph comprises:
determining that a first face of the first object mesh is within a collision distance of a second face of the second object mesh; and
in response, instantiating a face-face edge in the graph, wherein the face-face edge is a graph edge that connects: (i) a first set of graph nodes in the graph that represent the first face in the first object mesh, and (ii) a second set of graph nodes in the graph that represent the second face in the second object mesh;
processing the graph using a graph neural network to generate an updated graph; and
generating an updated environment mesh representing the state of the environment at a next time step using the updated graph.
